(19) United States
(12) Patent Application Publication
(10) Pub. No.: US 2026/0143959 A1
(43) Pub. Date: May 21, 2026

(54) DISPLAY DEVICE AND REPAIR METHOD THEREOF

(71) Applicant: Innolux Corporation, Miaoli County (TW)

(72) Inventors: Yu-Wei Tu, Miaoli County (TW); Yi-Cheng Tsai, Miaoli County (TW)

(73) Assignee: Innolux Corporation, Miaoli County (TW)

(21) Appl. No.: 19/365,193

(22) Filed: Oct. 22, 2025

Related U.S. Application Data
(60) Provisional application No. 63/722,074, filed on Nov. 19, 2024.

(30) Foreign Application Priority Data
Jun. 20, 2025 (CN) 202510834971.4

(51) Int. Cl. H10K 71/00; H10H 29/01; H10H 29/49; H10K 59/12; H10K 59/131

(52) U.S. Cl. CPC H10K 71/861; H10H 29/012; H10H 29/49; H10K 59/1201; H10K 59/131

(57) ABSTRACT

A display device including a first light-emitting unit, a second light-emitting unit, a first conductive wire, a first redundant pad, and a second redundant pad is provided. The first conductive wire is electrically connected to the first light-emitting unit and the second light-emitting unit. The first redundant pad is electrically connected to the first conductive wire. The second redundant pad is electrically connected to the first conductive wire. The first light-emitting unit has a first electrode and a second electrode, and the second light-emitting unit has a third electrode and a fourth electrode. The first conductive wire is electrically connected to the second electrode and the third electrode, and the second electrode and the third electrode have different polarities.

### CROSS-REFERENCE TO RELATED APPLICATION

This application claims the priority benefit of U.S. provisional application Ser. No. 63/722,074, filed on Nov. 19, 2024, and China application serial no. 202510834971.4, filed on Jun. 20, 2025. The entirety of each of the above-mentioned patent application is hereby incorporated by reference herein and made a part of this specification.

### BACKGROUND

### Technical Field

The disclosure relates to a display device and a repair method thereof.

### Description of Related Art

In some display devices, at least two light-emitting elements may be connected in series to improve the brightness of light emission. However, when at least one of the light-emitting elements has a defect, how to efficiently repair (e.g., reduce detection time and/or repair time), reduce cost, and/or reduce problems such as display quality degradation after repair still need to be solved.

### SUMMARY

The disclosure is directed to a display device.

A display device according to some embodiments of the disclosure is provided, which includes a first light-emitting unit, a second light-emitting unit, a first conductive wire, a first redundant pad, and a second redundant pad. The first conductive wire is electrically connected to the first light-emitting unit and the second light-emitting unit. The first redundant pad is electrically connected to the first conductive wire. The second redundant pad is electrically connected to the first conductive wire. The first light-emitting unit has a first electrode and a second electrode, the second light-emitting unit has a third electrode and a fourth electrode, the first conductive wire is electrically connected to the second electrode and the third electrode, and the second electrode and the third electrode have different polarities.

The disclosure is directed to a repair method of a display device, where the display quality of the repaired display device may be improved.

A repair method of a display device according to some embodiments of the disclosure is provided, where the display device includes a first light-emitting unit, a second light-emitting unit, a first group of redundant pads, and a second group of redundant pads, the first group of redundant pads is electrically connected to the first light-emitting unit, and the second group of redundant pads is electrically connected to the second light-emitting unit. The repair method of the display device provided by some embodiments of the disclosure includes the following steps. A substrate is provided, where the substrate includes a third light-emitting unit and a fourth light-emitting unit. The third light-emitting unit is bonded to the first group of redundant pads. The fourth light-emitting unit is bonded to the second group of redundant pads. The first group of redundant pads and the second group of redundant pads are connected in series with each other after the third light-emitting unit and the fourth light-emitting unit are joined.

### BRIEF DESCRIPTION OF THE DRAWINGS

FIG. 1 is a schematic flowchart of a repair method of a display device according to the first embodiment of the disclosure.

FIG. 2A is a schematic flowchart of a repair method of a display device according to the second embodiment of the disclosure.

FIG. 2B is a schematic cross-sectional diagram taken along line A-A′ of FIG. 2A.

FIG. 3 is a schematic flowchart of a repair method of a display device according to the third embodiment of the disclosure.

FIG. 4 is a schematic flowchart of a repair method of a display device according to the fourth embodiment of the disclosure.

FIG. 5 is a schematic flowchart of a repair method of a display device according to the fifth embodiment of the disclosure.

FIG. 6 is a schematic flowchart of a repair method of a display device according to the sixth embodiment of the disclosure.

FIG. 7 is a schematic flowchart of a repair method of a display device according to the seventh embodiment of the disclosure.

FIG. 8 is a schematic flowchart of a repair method of a display device according to the eighth embodiment of the disclosure.

FIG. 9A is a schematic flowchart of a repair method of a display device according to the ninth embodiment of the disclosure.

FIG. 9B is a shape of a light-emitting unit according to an embodiment of the disclosure.

### DESCRIPTION OF THE EMBODIMENTS

Reference will now be made in detail to the exemplary embodiments of the disclosure, examples of which are illustrated in the accompanying drawings. Wherever possible, the same reference numerals are used in the drawings and the description to refer to the same or like parts.

The disclosure may be understood by referring to the following detailed description in conjunction with the accompanying drawings. It should be noted that in order to facilitate understanding to the reader and to simplify the drawings, the plurality of drawings in the disclosure depict a part of the electronic device, and certain elements in the drawings are not drawn to actual scale. In addition, the number and size of each element in the figures are for illustration, and are not intended to limit the scope of the disclosure.

Certain terms are used throughout the specification and the appended claims of the disclosure to refer to particular elements. Those skilled in the art should understand that electronic equipment manufacturers may refer to the same elements under different names. This article is not intended to distinguish between elements having the same function but different names.

In the following description and claims, the words “including”, “containing”, “having” and the like are open-ended words, so they should be interpreted as meaning “including but not limited to . . . ”.

The ordinal numbers used in the specification and claims, such as the terms “first”, “second” and the like, to qualify an element do not imply or represent that the element or elements are preceded with any ordinal numbers, nor do they represent the order of a certain element and another element, or the order in manufacturing method, and are used only so as to clearly distinguish an element with one name from another element with the same name.

The directional terms mentioned in the disclosure, such as: “up”, “down”, “front”, “rear”, “left”, “right”, and so on, are used with reference to the accompanying drawings. Therefore, the directional terms used are for illustration, but not to limit, the disclosure.

Furthermore, when a component or film layer is referred to as being “on” or “above” another component or film layer, or as being “connected” to another component or film layer, it should be understood that the component or film layer is directly located on this other component or film layer, or is directly connected to the this other component or film layer, or there may be other components or film layers existing between the two (indirect case). Conversely, when a component or film layer is referred to as being “directly” “on” another component or film layer or “directly connected” to another component or film layer, it should be understood that there is no intervening component or film layer between the two.

The term “electrically connected” comprises any direct and indirect electrical connection means. Two components being electrically connected may be in direct contact to transmit electrical signals, with no other components between them. Alternatively, two components being electrically connected may transmit electrical signals through intermediate bridging components between them. “Electrically connected” herein may also be referred to as “coupled”.

The terms “about”, “substantially” or “approximately” are generally interpreted as being within 10%, 5%, 3%, 2%, 1%, or 0.5% of a given value or range.

In the disclosure, the measurement methods for length, thickness, width, height, distance and area may be obtained by optical microscope (OM), electron microscope (such as scanning electron microscope (SEM)) or other methods, but not limited thereto.

Unless otherwise defined, all terms (including technical and scientific terms) used herein have the same meaning as commonly understood by persons having ordinary skill in the art to which the disclosure belongs. It is understood that these terms, such as those defined in commonly used dictionaries, should be interpreted as having meanings consistent with the relevant art and the background or context of the disclosure, and should not be interpreted in an idealized or overly formal way, unless otherwise defined in the embodiments of the disclosure.

The electronic device of the disclosure may include, e.g., a light-emitting device, a display device, a sensing device, an antenna device, a touch device, a tiling device, or other suitable electronic devices, but not limited thereto. The display device may include light-emitting diodes, a color conversion layer, or other suitable materials, or a combination thereof, but not limited thereto. The display device may be applied to, e.g., notebook computers, public displays, tiled displays, automotive displays, touch displays, transparent displays, dual-sided displays, medical displays, virtual reality displays, augmented reality displays, 3D displays, monochrome displays, color displays, televisions, monitors, smartphones, tablet computers, light source modules, lighting equipment, military equipment, or electronic devices applied to the aforementioned products, but not limited thereto. The display device may include, e.g., liquid crystal molecules, light-emitting diodes, a color conversion layer, other suitable display media, or a combination thereof, but not limited thereto. The display device may include a liquid crystal display device, an electro-phoretic display device, or other suitable devices, but not limited thereto. The sensing device may be, e.g., a sensing device for detecting capacitance changes, light, thermal energy or ultrasonic waves, but not limited thereto. The tiling device may include, e.g., a tiled display device or a tiled antenna device, but not limited thereto. The electronic device may include an electronic unit, where the electronic unit may include a passive component and an active component, such as a capacitor, a resistor, an inductor, a diode, a transistor, a sensor, a light-emitting unit, etc. The following uses a display device as the electronic device and light-emitting unit as the electronic unit to explain the content of the disclosure, but not limited thereto.

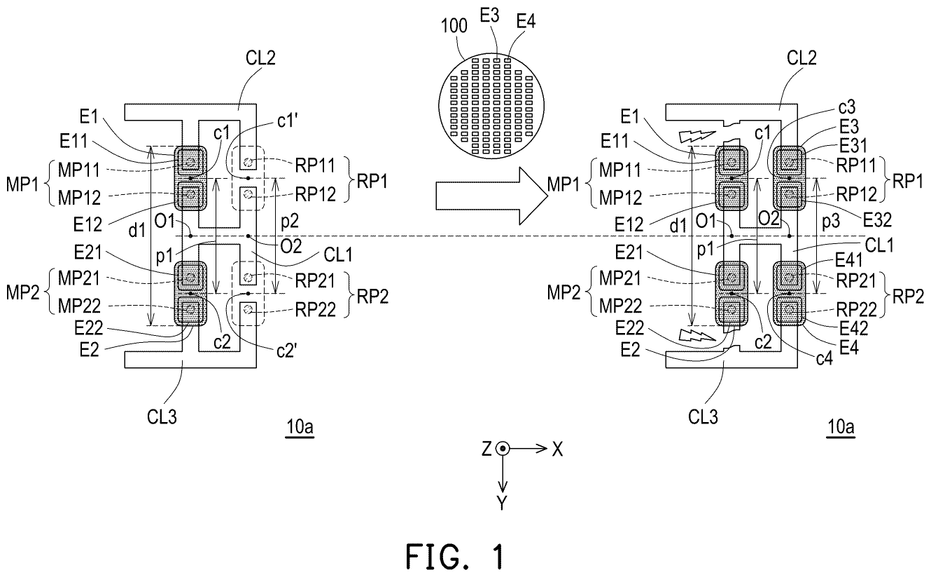

FIG. 1 is a schematic flowchart of a repair method of a display device according to the first embodiment of the disclosure. It is worth explaining that the flowchart is only an example and is not used to limit the steps of the repair method of the display device.

Referring to FIG. 1, the embodiment provides a repair method of a display device 10a. In the embodiment, the display device 10a includes a first light-emitting unit E1, a second light-emitting unit E2, a first group of pads MP1, a second group of pads MP2, a first group of redundant pads RP1, and a second group of redundant pads RP2.

In the embodiment, the first light-emitting unit E1 and the second light-emitting unit E2 are arranged in a direction Y. The first light-emitting unit E1 and the second light-emitting unit E2 may, e.g., emit various suitable color lights. In the disclosure, multiple light-emitting units of one pixel may be used to provide the same color and be driven through the same driving circuit and driving transistors. The first light-emitting unit E1 and the second light-emitting unit E2 are used to provide light of the same color, but not limited thereto. In some embodiments, the first light-emitting unit E1 and the second light-emitting unit E2 may each include self-luminous material. The first light-emitting unit E1 and the second light-emitting unit E2 are light emitting diodes (LEDs), but not limited thereto. In some embodiments, the first light-emitting unit E1 and the second light-emitting unit E2 may each include organic light emitting diodes (OLEDs), micro light emitting diodes (micro LEDs), mini light emitting diodes (mini LEDs), quantum dot light emitting diodes (quantum dot LEDs, which may include QLEDs, QDLEDs), or a combination thereof. In the embodiment, the shapes of the first light-emitting unit E1 and the second light-emitting unit E2 in a direction Z (top view direction) are rectangular, but not limited thereto.

The first light-emitting unit E1 and the second light-emitting unit E2 are respectively disposed on and electrically connected with the first group of pads MP1 and the second group of pads MP2. In detail, the first light-emitting unit E1 has a first electrode E11 and a second electrode E12 electrically connected with a pad MP11 and a pad MP12 of the first group of pads MP1, and the second light-emitting unit E2 has a third electrode E21 and a fourth electrode E22 electrically connected with a pad MP21 and a pad MP22 of the second group of pads MP2. The first electrode E11 and the third electrode E21 have the same polarity (e.g., both are p-type (anode)), and the second electrode E12 and the fourth electrode E22 have the same polarity (e.g., both are n-type (cathode)), but not limited thereto. Based on this, the first light-emitting unit E1 and the second light-emitting unit E2 are in a series connection relationship with each other. In the embodiment, the first group of pads MP1 and the second group of pads MP2 are arranged in the direction Y. The first group of pads MP1 includes the pad MP11 and the pad MP12 separated from each other and arranged along the direction Y, and the second group of pads MP2 includes the pad MP21 and the pad MP22 separated from each other and arranged along the direction Y. The material of the first group of pads MP1 and the material of the second group of pads MP2 may include metal, metal oxide, or other suitable conductive materials.

The first group of redundant pads RP1 and the second group of redundant pads RP2 separated from each other and are arranged in the direction Y, where the first group of redundant pads RP1 includes a redundant pad RP11 and a redundant pad RP12 separated from each other and are arranged in the direction Y, and the second group of redundant pads RP2 includes a redundant pad RP21 and a redundant pad RP22 separated from each other and are arranged in the direction Y. The redundant pad RP11 is electrically connected to the first electrode E11, and the redundant pad RP12 is electrically connected to the second electrode E12. The redundant pad RP21 is electrically connected to the third electrode E21, and redundant pad RP22 is electrically connected to the fourth electrode E22. The material of the first group of redundant pads RP1 and the material of the second group of redundant pads RP2 may be the same as or similar to the material of the first group of pads MP1 and the material of the second group of pads MP2.

In the embodiment, the first light-emitting unit E1 and the second light-emitting unit E2 have a pitch p1 in the direction Y, and the first group of redundant pads RP1 and the second group of redundant pads RP2 have a pitch p2 in the direction Y. It is worth explaining that the pitch p1 may be defined as the distance in the direction Y between a center position c1 of the first light-emitting unit E1 and a center position c2 of the second light-emitting unit E2, or the distance in the direction Y between the same-side edges of the first light-emitting unit E1 and the second light-emitting unit E2, and the pitch p2 may be defined as the distance in the direction Y between a center position c1′ of the first group of redundant pads RP1 (e.g., the center position of the redundant pad RP11 and the redundant pad RP12) and a center position c2′ of the second group of redundant pads RP2 (e.g., the center position of the redundant pad RP21 and the redundant pad RP22). In some embodiments, the pitch p1 and the pitch p2 conform to a relationship below: p1*0.9≤p2≤p1*1.1. In the embodiment, the pitch p1 is equal to the pitch p2 (i.e., p1=p2).

Additionally, all light-emitting units of one pixel before repair have a farthest distance d1 in the direction Y. For example, the farthest distance d1 may be the distance in the direction Y between the edge of the first light-emitting unit E1 away from the second light-emitting unit E2 and the edge of the second light-emitting unit E2 away from the first light-emitting unit E1. In the embodiment, the first light-emitting unit E1 and the second light-emitting unit E2 have a first center position O1 (or, the pixel center position O1 before repair), the first group of redundant pads RP1 and the second group of redundant pads RP2 have a second center position O2, where the distance between the first center position O1 and the second center position O2 in the direction Y is less than or equal to the farthest distance d1. Therefore, after transferring a third light-emitting unit E3 and a fourth light-emitting unit E4 to the first group of redundant pads RP1 and the second group of redundant pads RP2, the pixel composed of the third light-emitting unit E3 and the fourth light-emitting unit E4 does not have an offset in direction Y compared to the pixel composed of the first light-emitting unit E1 and the second light-emitting unit E2, which may reduce the possibility of display quality degradation of the display device. In this disclosure, the first center position O1 may be the center point of the pitch p1, the second center position O2 may be the center point of the pitch p2.

In the embodiment, the display device 10a may further include multiple conductive wires CL. The shape of the multiple conductive wires CL in the direction Z may be a line, a bent line, a curve, or other irregular shapes. The multiple conductive wires CL may include a conductive wire CL1, a conductive wire CL2, and a conductive wire CL3 as shown in FIG. 1. In some embodiments, the conductive wire CL1, the conductive wire CL2, and the conductive wire CL3 belong to the same layer and are conductive patterns separated from each other. In other embodiments, at least two of the conductive wire CL1, the conductive wire CL2, and the conductive wire CL3 are conductive patterns in different layers.

The conductive wire CL1 is electrically connected to and overlap with the pad MP12, the pad MP21, the redundant pad RP12, and the redundant pad RP21. The conductive wire CL1 may present an “H” shape in a top view direction.

The conductive wire CL1 is electrically connected to the first light-emitting unit E1 and the second light-emitting unit E2.

The conductive wire CL2 is, e.g., electrically connected to and overlap with the pad MP11 and the redundant pad RP11. The conductive wire CL2 may present a shape of “F rotated 90 degrees clockwise” in a top view direction.

The conductive wire CL3 is electrically connected to and overlap with the pad MP22 and the redundant pad RP22. The conductive wire CL2 may present a shape of “inverted F rotated 90 degrees clockwise” in a top view direction.

In the embodiment, the conductive wire CL1 is disposed between and separated from the conductive wire CL2 and the conductive wire CL3 in the direction Y.

In the embodiment, the first electrode E11 and the second electrode E12 have a first arrangement direction (e.g., direction Y), the third electrode E21 and the fourth electrode E22 have a second arrangement direction (e.g., direction Y), and the first arrangement direction and the second arrangement direction are the same.

Continuing to refer to FIG. 1, in some embodiments, the first light-emitting unit E1 and the second light-emitting unit E2 may be detected to check whether a defect occurs. For example, appearance inspection and/or electrical inspection may be performed on the first light-emitting unit E1 and the second light-emitting unit E2 to detect whether the first light-emitting unit E1 or the second light-emitting unit E2 has bad points. For example, appearance inspection may be performed on the first light-emitting unit E1 and the second light-emitting unit E2 by using automated optical inspection (AOI) to observe whether the first light-emitting unit E1 and the second light-emitting unit E2 have phenomena of appearance defects such as damage, scratches, displacement, etc. ; alternatively, electrical inspection may be performed on the first light-emitting unit E1 and the second light-emitting unit E2 by using open/short test (O/S test) to make the first light-emitting unit E1 and the second light-emitting unit E2 emit light to confirm the quality of the light they emit. In the embodiment, when it is detected that at least one of the first light-emitting unit E1 and the second light-emitting unit E2 has a defect, the repair method of the display device shown below may be performed.

Continuing to refer to FIG. 1, a substrate 100 is provided, where the substrate 100 includes a plurality of light-emitting elements. In the embodiment, the substrate 100 may include the third light-emitting unit E3 and the fourth light-emitting unit E4 to be respectively transferred to the first group of redundant pads RP1 and the second group of redundant pads RP2.

Continuing to refer to FIG. 1, the third light-emitting unit E3 is bonded to the first group of redundant pads RP1, and the fourth light-emitting unit E4 is bonded to the second group of redundant pads RP2.

Continuing to refer to FIG. 1, a laser cutting process may be used to cut off a portion of the conductive wire electrically connected to the first light-emitting unit E1 (for example, the first conductive wire CL1 and/or the second conductive wire CL2) and a portion of the conductive wire electrically connected to the second light-emitting unit E2 (for example, the first conductive wire CL1 and/or the third conductive wire CL3), so as to reduce the influence on the third light-emitting unit E3 and/or the fourth light-emitting unit E4.

In the embodiment, the third light-emitting unit E3 and the fourth light-emitting unit E4 have a pitch p3 in the direction Y. It is worth explaining that the pitch p3 may be defined as the distance between a center position c3 of the third light-emitting unit E3 and a center position c4 of the fourth light-emitting unit E4 in the direction Y, or the distance between the same side edges of the third light-emitting unit E3 and the fourth light-emitting unit E4 in the direction Y, but not limited thereto. In some embodiments, the pitch p3 and the pitch p1 conform to a relationship below: p1*0.9≤p3≤p1*1.1. In the embodiment, the pitch p3 is equal to the pitch p1 (i.e., p3=p1).

Based on the above, when it is detected that at least one of the first light-emitting unit E1 and the second light-emitting unit E2 has a defect, by performing the repair method of the embodiment to dispose the third light-emitting unit E3 and the fourth light-emitting unit E4, after transferring the third light-emitting unit E3 and the fourth light-emitting unit E4, the pixel composed of the third light-emitting unit E3 and the fourth light-emitting unit E4 has no offset in the direction Y compared to the pixel composed of the first light-emitting unit E1 and the second light-emitting unit E2, which may reduce the possibility of display quality degradation of the display device.

Furthermore, since the first light-emitting unit E1 and the second light-emitting unit E2 are connected in series, the first light-emitting unit E1 and the second light-emitting unit E2 may be detected together, and when a defect is detected, the third light-emitting unit E3 and the fourth light-emitting unit E4 may be simultaneously transferred for repair, which may reduce detection time and/or repair time.

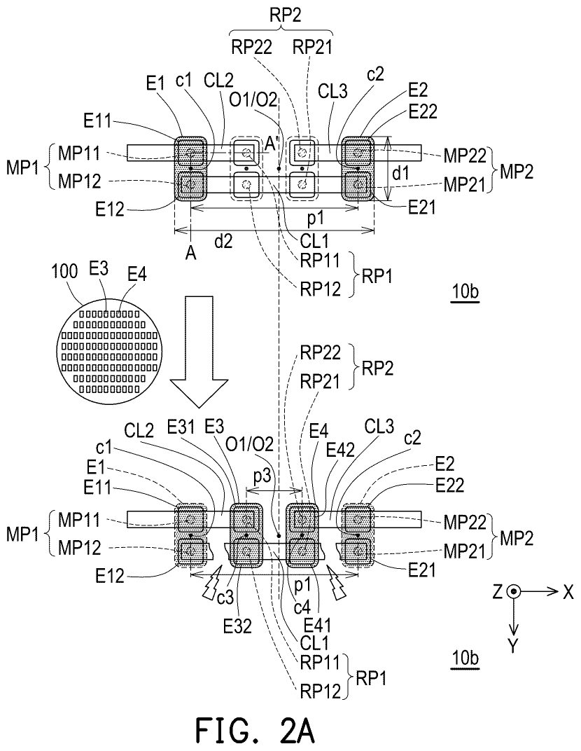

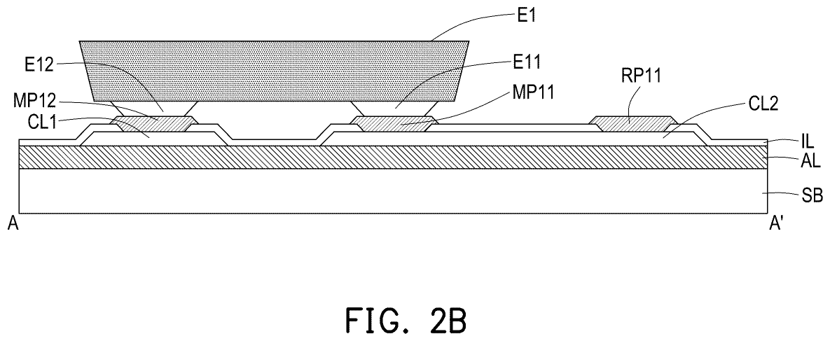

Referring to FIG. 2A, the following will state the main differences between the display device 10b and the display device 10a.

The conductive wire CL1, the conductive wire CL2, and the conductive wire CL3 are lines extending in a direction X, but not limited thereto. As mentioned above, the conductive wire CL1, the conductive wire CL2, and the conductive wire CL3 are conductive patterns separated from each other.

The first light-emitting unit E1 and the second light-emitting unit E2 are arranged in the direction X. The first electrode E11 and the second electrode E12 have a first arrangement direction (e.g., direction Y), the third electrode E21 and the fourth electrode E22 have a second arrangement direction (e.g., opposite direction of direction Y), and the first arrangement direction is different from the second arrangement direction.

After the third light-emitting unit E3 and the fourth light-emitting unit E4 are respectively bonded to the first group of redundant pads RP1 and the second group of redundant pads RP2, the third light-emitting unit E3 and the fourth light-emitting unit E4 have a pitch p3 in the direction X. In the embodiment, the pitch p3 is smaller than the pitch p1.

Additionally all light-emitting units of one pixel before repair have a farthest distance d1 in the direction Y and a farthest distance d2 in the direction X. The farthest distance d1 and the farthest distance d2 may respectively be the distance between the two farthest edges of the first light-emitting unit E1 and the second light-emitting unit E2 in the direction Y and the distance between the other two farthest edges in the direction X. The first light-emitting unit E1 and the second light-emitting unit E2 have a first center position O1 (or, the pixel center position O1 before repair), the first group of redundant pads RP1 and the second group of redundant pads RP2 have a second center position O2, where the first center position O1 and the second center position O2 substantially overlap. Therefore, after transferring the third light-emitting unit E3 and the fourth light-emitting unit E4 to the first group of redundant pads RP1 and the second group of redundant pads RP2, the pixel composed of the third light-emitting unit E3 and the fourth light-emitting unit E4 has no offset in the direction X and the direction Y compared with the pixel composed of the first light-emitting unit E1 and the second light-emitting unit E2. Since the distance between the first center position O1 and the second center position O2 in the direction Y is smaller than or equal to the farthest distance d1, and the distance between the first center position O1 and the second center position O2 in the direction X is smaller than or equal to the farthest distance d2, the possibility of display quality degradation of the display device may be reduced.

The conductive wire electrically connected to the second light-emitting unit E2 (e.g., another portion of the first conductive wire CL1) may be cut through a laser cutting process to reduce the influence on the third light-emitting unit E3 and/or the fourth light-emitting unit E4. It is worth explaining that the pads MP and redundant pads RP of all embodiments of the disclosure may exchange positions with each other. For example, the positions between the first group of redundant pads RP1 and the first group of pads MP1 and/or between the second group of redundant pads RP2 and the second group of pads MP2 may be exchanged with each other. Since the arrangement of pads and redundant pads changes according to requirements, the conductive wire cut through the laser cutting process after repair may therefore be different.

Referring to FIG. 2B, the display device 10b may include a substrate SB, a component layer AL, and an insulating layer IL. It is worth explaining that the schematic cross-sectional diagram shown in FIG. 2B may also be applied to the display device 10a of the above embodiment and the display devices 10c to 10g, 20a to 20b to be introduced in the following embodiments.

The component layer AL is, e.g., disposed on the substrate SB. In some embodiments, the component layer AL may include multiple signal lines (not shown), multiple transistors (not shown) and/or multiple electrodes (not shown). The above multiple signal lines may, e.g., include multiple data lines (not shown), multiple scan lines (not shown) and/or other signal lines suitable for the display device 10b (e.g., common voltage lines, power supply lines, light emission control signal lines, operation signal lines, etc.). In some embodiments, the material of the component layer AL may, e.g., include a conductive material, a semiconductor material, an organic material, an inorganic material, or a combination thereof. The conductive material may include a transparent conductive material, metal, or a combination thereof. The metal may include Cu, Mo, Al, Ti, other metals suitable for the display device 10b, or an alloy thereof, and the transparent conductive material may include ITO, IZO, or a combination thereof. The semiconductor material may include amorphous silicon (a-Si), low temperature polycrystalline silicon (LTPS), oxide semiconductor, or other suitable semiconductor materials. The organic material may include polyimide (PI), photosensitive polyimide (PSPI), epoxy, polymer, or other suitable materials. The inorganic material may include silicon oxide (SiOₓ), silicon nitride (SiNₓ), silicon oxynitride, other suitable insulating materials, or a combination of the above materials.

The insulating layer IL is disposed on the component layer AL, and exposes at least part of the conductive wire CL1, part of the conductive wire CL2, and part of the conductive wire CL3, so that the first group of pads MP1, the second group of pads MP2, the first group of redundant pads RP1, and the second group of redundant pads RP2 disposed on the insulating layer IL may be electrically connected with the corresponding conductive wires CL. In some embodiments, the material of the insulating layer IL may be silicon oxide, silicon nitride, silicon oxynitride, or a combination thereof.

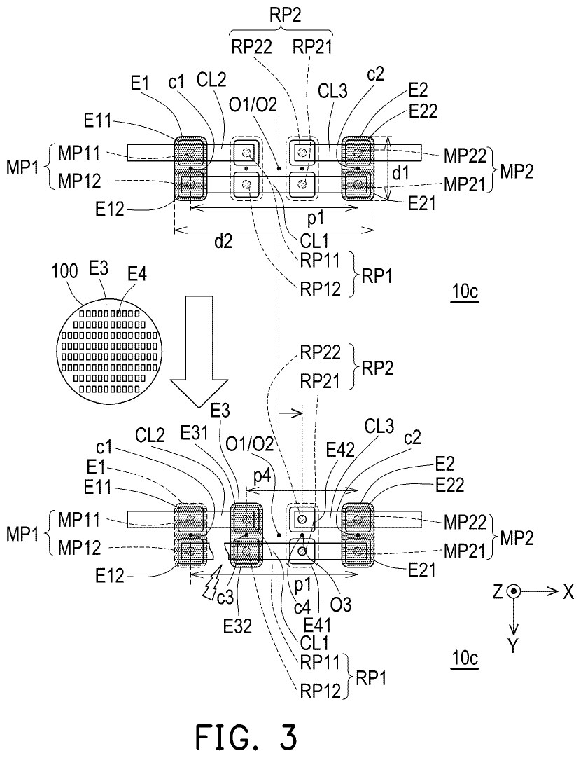

Referring to FIG. 3, the following will state the main differences between the display device 10c and the display device 10b.

In the embodiment, the first light-emitting unit E1 is detected and determined to have a defect, and the second light-emitting unit E2 is detected and determined to be capable of emitting light normally. Based on this, the third light-emitting unit E3 is bonded to the first group of redundant pads RP1, while the second light-emitting unit E2 is retained. That is, the fourth light-emitting unit E4 is not bonded to the second group of redundant pads RP2. In some embodiments, a laser cutting process may be used to cut off a part of the wire electrically connected with the first light-emitting unit E1 (e.g., a part of the first conductive wire CL1), so as to reduce the influence on the third light-emitting unit E3.

In the embodiment, after the third light-emitting unit E3 is bonded to the first group of redundant pads RP1, the third light-emitting unit E3 and the second light-emitting unit E2 have a pitch p4 in the direction Y. In the embodiment, the pitch p4 is smaller than the pitch p1.

Based on the above, when the first light-emitting unit E1 is detected to have a defect, the third light-emitting unit E3 is disposed by performing the repair method of the embodiment. The repaired pixel center position O3 (that is, the center position between the third light-emitting unit E3 and the second light-emitting unit E2) compared to the pixel center position O1 before repair (that is, the center position O1 of the first light-emitting unit E1 and the second light-emitting unit E2) does not have offset in the direction Y. Therefore, the possibility of display quality degradation of the display device may be reduced.

In addition, since the second light-emitting unit E2 that may emit light normally is retained (that is, the fourth light-emitting unit E4 is not transferred), the process cost of the display device may be reduced.

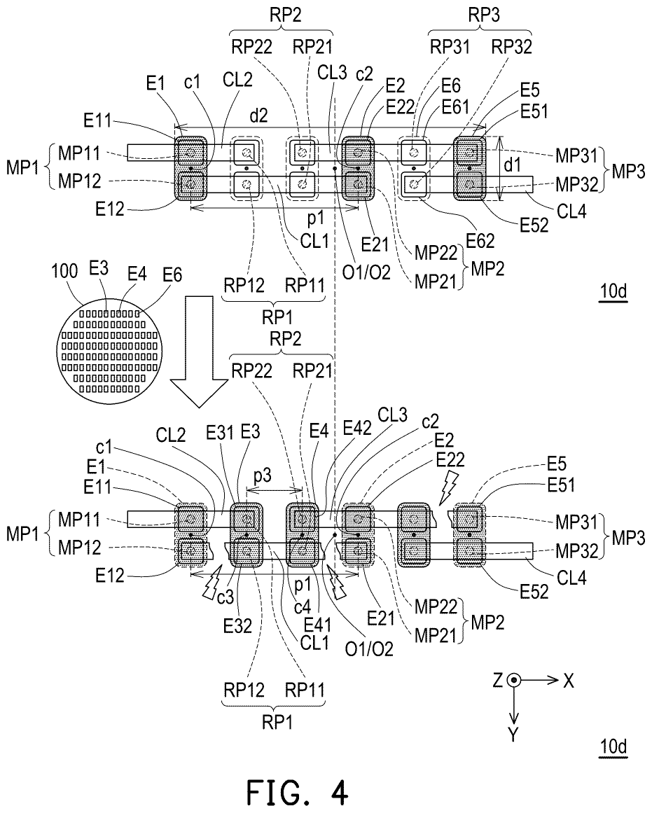

Referring to FIG. 4, the following will state the main differences between the display device 10d and the display device 10b.

The conductive wire CL in the display device 10d further includes a conductive wire CL4. The conductive wire CL4 is also a line extending in the direction X, but not limited thereto. The conductive wire CL4, the conductive wire CL3, and the conductive wire CL1 are conductive patterns separated from each other.

In the embodiment, the display device 10d further includes a fifth light-emitting unit E5. The fifth light-emitting unit E5 is disposed on and is electrically connected to a third group of pads MP3. The fifth light-emitting unit E5 has a fifth electrode E51 and a sixth electrode E52, where the fifth electrode E51 is a p-type electrode (anode), and the sixth electrode E52 is an n-type electrode (cathode). Based on this, the fifth light-emitting unit E5, the second light-emitting unit E2, and the first light-emitting unit E1 are in a series connection relationship with each other. The third group of pads MP3 includes a pad MP31 and a pad MP32 separated from each other and arranged along the direction Y.

In the embodiment, the fifth electrode E51 and the sixth electrode E52 have a third arrangement direction (e.g., direction Y), the third electrode E21 and the fourth electrode E22 have a second arrangement direction (e.g., opposite direction of direction Y), and the third arrangement direction is different from the second arrangement direction.

Continuing to refer to FIG. 4, a substrate 100 is provided, where the substrate 100 may further include a sixth light-emitting unit E6 to be transferred to a third group of redundant pads RP3.

Continuing to refer to FIG. 4, the sixth light-emitting unit E6 is bonded to the third group of redundant pads RP3. In some embodiments, the sixth light-emitting unit E6 may be disposed on the third group of redundant pads RP3 through mass transfer, so that it is electrically connected to the third group of redundant pads RP3. In detail, a first electrode E61 is electrically connected to a redundant pad RP31, and a second electrode E62 is electrically connected to a redundant pad RP32.

Continuing to refer to FIG. 4, a laser cutting process may be used to cut off a portion of the wire electrically connected to the first light-emitting unit E1 (e.g., a portion of the first conductive wire CL1), a portion of the wire electrically connected to the second light-emitting unit E2 (e.g., another portion of the first conductive wire CL1), and a portion of the wire electrically connected to the fifth light-emitting unit E5 (e.g., a portion of the third conductive wire CL3), so as to reduce the influence on the third light-emitting unit E3, the fourth light-emitting unit E4, and/or the sixth light-emitting unit E6.

In the embodiment, the first light-emitting unit E1, the second light-emitting unit E2, and the fifth light-emitting unit E5 belong to the same pixel, where the farthest distance d1 and the farthest distance d2 may respectively be the distance of the farthest two edges of the first light-emitting unit E1, the second light-emitting unit E2, and the fifth light-emitting unit E5 in the direction Y and the distance of the farthest other two edges in the direction X. For example, referring to FIG. 4, the first center position O1 (or, the pixel center position O1 before repair) may be the center position of the first light-emitting unit E1 and the fifth light-emitting unit E5, and the second center position O2 may be the center position of the first group of redundant pads RP1 and the third group of redundant pads RP3. In the embodiment, the first center position O1 and the second center position O2 substantially overlap. Therefore, after transferring the third light-emitting unit E3, the fourth light-emitting unit E4, and the sixth light-emitting unit E6 to the first group of redundant pads RP1, the second group of redundant pads RP2, and the third group of redundant pads RP3, the pixel composed of the third light-emitting unit E3, the fourth light-emitting unit E4, and the sixth light-emitting unit E6 has no offset in both direction X and direction Y compared to the pixel composed of the first light-emitting unit E1, the second light-emitting unit E2, and the fifth light-emitting unit E5. The distance between the first center position O1 and the second center position in the direction Y is less than or equal to the farthest distance d1, and the distance between the first center position O1 and the second center position O2 in the direction X is less than or equal to the farthest distance d2, thereby reducing the possibility of display quality degradation of the display device.

Furthermore, when a defect is detected, the third light-emitting unit E3, the fourth light-emitting unit E4, and the sixth light-emitting unit E6 may be simultaneously transferred for repair, which may reduce detection time and/or repair time.

Additionally, through the configuration method of the first group of pads MP1 to the third group of pads MP3 and the first group of redundant pads RP1 to the third group of redundant pads RP3, the display device 10d may save relatively more layout space.

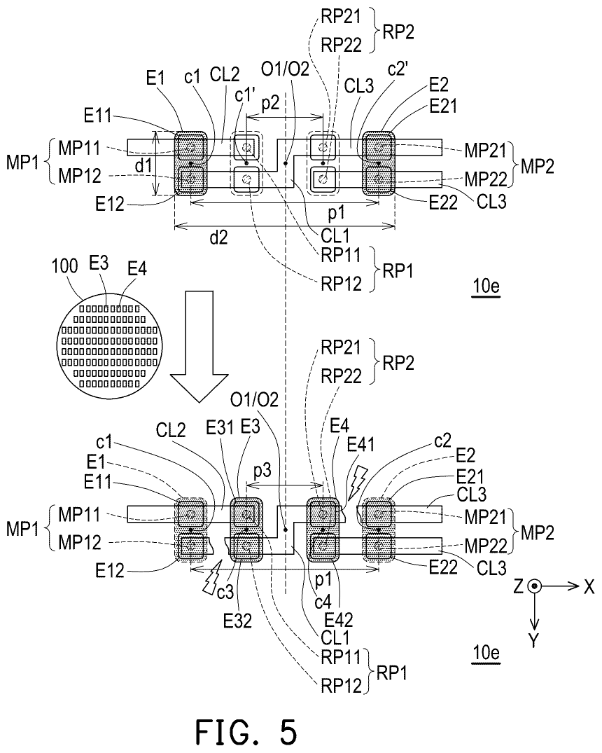

Referring to FIG. 5, the following will state the main differences between the display device 10e and the display device 10b.

The conductive wire CL1 is a bent line extending in the direction X. In detail, the conductive wire CL1 may be composed of two lines extending in the direction X and one line extending in the direction Y, where both ends of the line extending in the direction Y are each connected to one endpoint of the two lines extending in the direction X. The conductive wire CL2 and the conductive wire CL3 are lines extending in the direction X and separated by the conductive wire CL1.

In the embodiment, the first electrode E11 and the second electrode E12 have a first arrangement direction (e.g., direction Y), the third electrode E21 and the fourth electrode E22 have a second arrangement direction (e.g., direction Y), and the first arrangement direction and the second arrangement direction are the same.

Since the first arrangement direction is the same as the second arrangement direction, the third light-emitting unit E3 and the fourth light-emitting unit E4 may be simultaneously transferred to the first group of redundant pads RP1 and the second group of redundant pads RP2 through performing one transfer process, which may reduce repair time and/or process cost.

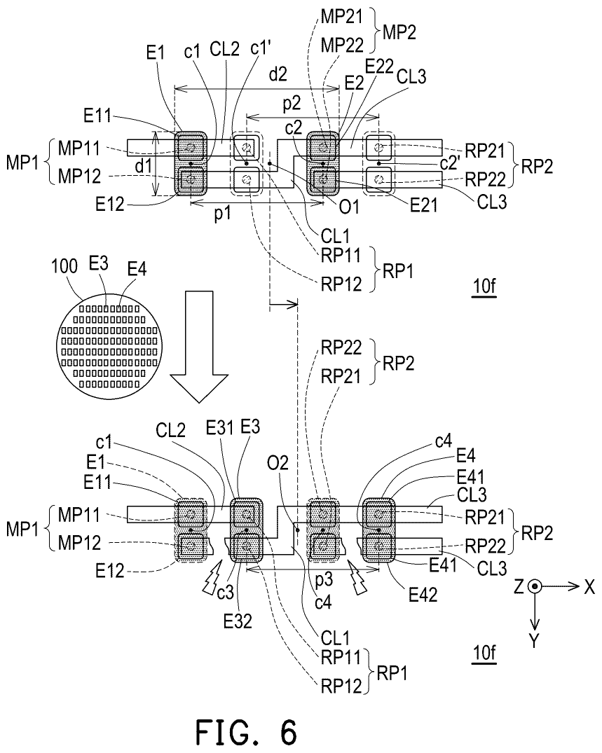

Referring to FIG. 6, the following will state the main differences between the display device 10f and the display device 10e.

In the embodiment, the first group of redundant pads RP1 and the second group of pads MP2 are disposed between the first group of pads MP1 and the second group of redundant pads RP2. After the third light-emitting unit E3 and the fourth light-emitting unit E4 are respectively bonded to the first group of redundant pads RP1 and the second group of redundant pads RP2, the pitch p3 and the pitch p1 conform to a relationship below: p1*0.9≤p3≤p1*1.1. For example, the pitch p3 is equal to the pitch p1. In other words, the dimension of the pixel composed of the third light-emitting unit E3 and the fourth light-emitting unit E4 may be the same as the dimension of the pixel composed of the first light-emitting unit E1 and the second light-emitting unit E2.

After the third light-emitting unit E3 and the fourth light-emitting unit E4 are respectively bonded to the first group of redundant pads RP1 and the second group of redundant pads RP2, a laser cutting process may be performed to cut off a portion of the wire electrically connected to the first light-emitting unit E1 (e.g., a portion of the first conductive wire CL1) and a portion of the wire electrically connected to the second light-emitting unit E2 (e.g., a portion of the third conductive wire CL3), so as to reduce the influence on the third light-emitting unit E3 and/or the fourth light-emitting unit E4.

In the embodiment, the distance between the first center position O1 and the second center position in the direction Y is less than or equal to the farthest distance d1, and the distance between the first center position O1 and the second center position O2 in the direction X is less than or equal to the farthest distance d2.

Based on the above, when it is detected that at least one of the first light-emitting unit E1 and the second light-emitting unit E2 has a defect, by performing the repair method of the embodiment to dispose the third light-emitting unit E3 and the fourth light-emitting unit E4, the pixel composed of the third light-emitting unit E3 and the fourth light-emitting unit E4 has no offset in the direction Y compared to the pixel composed of the first light-emitting unit E1 and the second light-emitting unit E2, which may reduce the possibility of display quality degradation of the display device.

In addition, since the dimension of the pixel composed of the third light-emitting unit E3 and the fourth light-emitting unit E4 is the same as the dimension of the pixel composed of the first light-emitting unit E1 and the second light-emitting unit E2, the complexity of the process may be reduced.

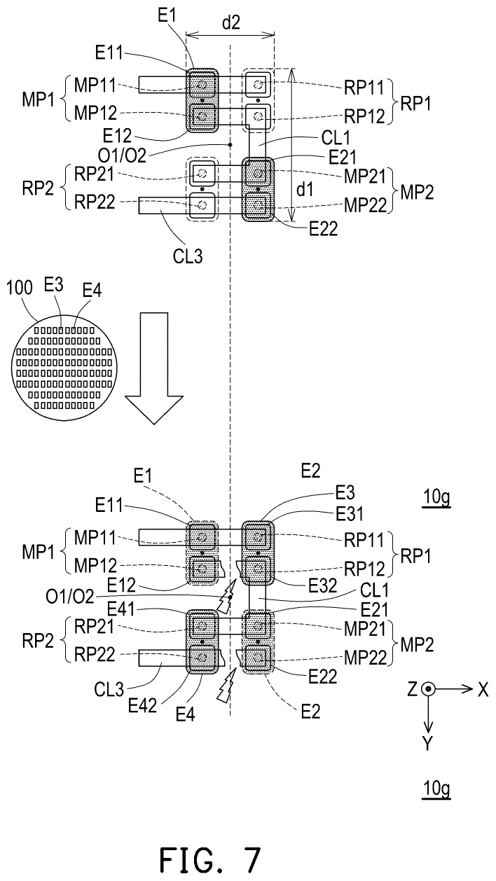

Referring to FIG. 7, the following will state the main differences between the display device 10g and the display device 10a.

In the embodiment, the conductive wire CL1 presents an “inverted □” shape in a top view direction, the conductive wire CL2 and the conductive wire CL3 are lines extending in the direction X, and the conductive wire CL1 is disposed between the conductive wire CL2 and the conductive wire CL3 in the direction Y.

In the embodiment, the first group of pads MP1 and the first group of redundant pads RP1 are arranged in the direction X, the second group of redundant pads RP2 and the second group of pads MP2 are arranged in the direction X, the first group of pads MP1 and the second group of redundant pads RP2 are arranged in the direction Y, and the first group of redundant pads RP1 and the second group of pads MP2 are arranged in the direction Y. Based on this, after transferring the third light-emitting unit E3 and the fourth light-emitting unit E4 to the first group of redundant pads RP1 and the second group of redundant pads RP2 respectively, the dimension of the pixel composed of the third light-emitting unit E3 and the fourth light-emitting unit E4 may be the same as the dimension of the pixel composed of the first light-emitting unit E1 and the second light-emitting unit E2.

After the third light-emitting unit E3 and the fourth light-emitting unit E4 are respectively bonded to the first group of redundant pads RP1 and the second group of redundant pads RP2, a laser cutting process may be used to cut off a portion of the first conductive wire CL1 electrically connected to the first light-emitting unit E1 and a portion of the third conductive wire CL3 electrically connected to the second light-emitting unit E2, so as to reduce the influence on the third light-emitting unit E3 and/or the fourth light-emitting unit E4.

Based on the above, when detecting that at least one of the first light-emitting unit E1 and the second light-emitting unit E2 has a defect, by performing the repair method of the embodiment to dispose the third light-emitting unit E3 and the fourth light-emitting unit E4, the pixel composed of the third light-emitting unit E3 and the fourth light-emitting unit E4 compared to the pixel composed of the first light-emitting unit E1 and the second light-emitting unit E2 has no offset in both direction X and direction Y, which may reduce the possibility of display quality degradation of the display device.

Additionally, since the arrangement direction of the first electrode E31 and the second electrode E32 is the same as the arrangement direction of the third electrode E41 and the fourth electrode E42, the third light-emitting unit E3 and the fourth light-emitting unit E4 may be simultaneously transferred to the first group of redundant pads RP1 and the second group of redundant pads RP2 by performing one transfer process, which may reduce repair time and/or process cost.

Furthermore, since the dimension of the pixel composed of the third light-emitting unit E3 and the fourth light-emitting unit E4 is the same as the dimension of the pixel composed of the first light-emitting unit E1 and the second light-emitting unit E2, the complexity of the process may be reduced.

Additionally, the first group of pads MP1, the first group of redundant pads RP1, the second group of redundant pads RP2, and the second group of pads MP2 are arranged in an array with each other to form a rectangular shape, which may improve the utilization rate of the multiple light-emitting elements disposed on the substrate 100.

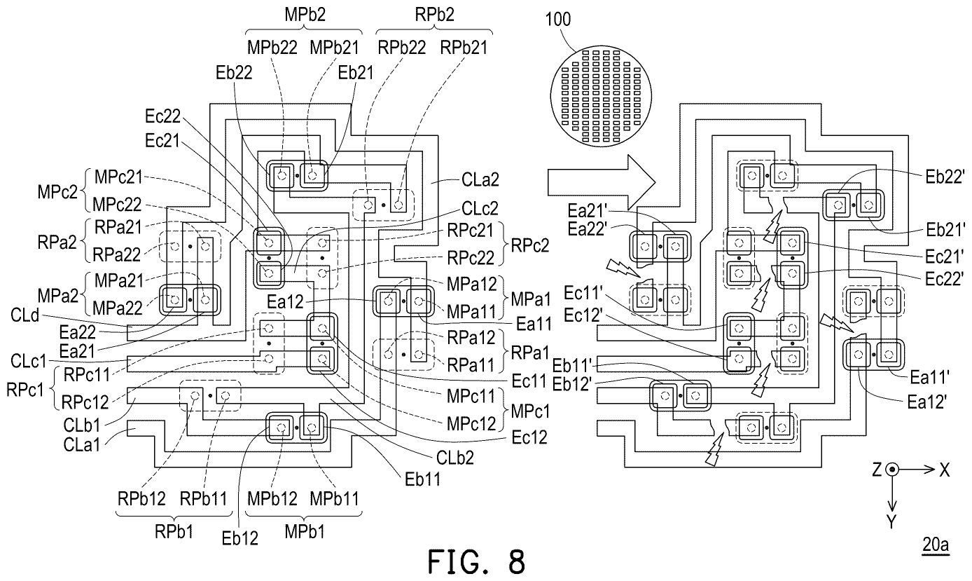

Referring to FIG. 8, the following will state the main differences between the display device 20a and the display device 10a.

The light-emitting units E in the display device includes a first group of light-emitting units Ea, a second group of light-emitting units Eb, and a third group of light-emitting units Ec, where the wavelength of light emitted by the first group of light-emitting units Ea is greater than the wavelength of light emitted by the second group of light-emitting units Eb, and the wavelength of light emitted by the second group of light-emitting units Eb is greater than the wavelength of light emitted by the third group of light-emitting units Ec. In the embodiment, the first group of light-emitting units Ea are red light-emitting units, the second group of light-emitting units Eb are green light-emitting units, and the third group of light-emitting units Ec are blue light-emitting units

The first group of light-emitting units Ea, the second group of light-emitting units Eb, and the third group of light-emitting units Ec are respectively disposed on and electrically connected with a first group of pads MPa, a second group of pads MPb, and a third group of pads MPc. In detail, the first group of light-emitting units Ea includes a light-emitting unit Ea1 having electrodes Ea11, Ea12 and a light-emitting unit Ea2 having electrodes Ea21, Ea22, the second group of light-emitting units Eb includes a light-emitting unit Eb1 having electrodes Eb11, Eb12 and a light-emitting unit Eb2 having electrodes Eb21, Eb22, the third group of light-emitting units Ec includes a light-emitting unit Ec1 having electrodes Ec11, Ec12 and a light-emitting unit Ec2 having electrodes Ec21, Ec22.

In the embodiment, the first group of pads MPa includes a pad MPa1 having pads MPa11, MPa12 and a pad MPa2 having pads MPa21, MPa22, the second group of pads MPb includes a pad MPb1 having pads MPb11, MPb12 and a pad MPb2 having pads MPb21, MPb22, and the third group of pads MPc includes a pad MPc1 having pads MPc11, MPc12 and a pad MPc2 having pads MPc21, MPc22. The electrodes Ea11, Ea12 are respectively electrically connected with the pads MPa11, MPa12, and the electrodes Ea21, Ea22 are electrically connected with the pads MPa21, MPa22. The electrodes Eb11, Eb12 are electrically connected with the pads MPb11, MPb12, and the electrodes Eb21, Eb22 are electrically connected with the pads MPb21, MPb22. The electrodes Ec11, Ec12 are electrically connected with the pads MPc11, MPc12, and the electrodes Ec21, Ec22 are electrically connected with the pads MPc21, MPc22.

The first group of redundant pads RPa includes a redundant pad RPa1 having redundant pads RPa11, RPa12 and a redundant pad RPa2 having redundant pads RPa21, RPa22, the second group of redundant pads RPb includes a redundant pad RPb1 having redundant pads RPb11, RPb12 and a redundant pad RPb2 having redundant pads RPb21, RPb22, and the third group of redundant pads RPc includes a redundant pad RPc1 having redundant pads RPc11, RPc12 and a redundant pad RPc2 having redundant pads RPc21, RPc22.

The conductive wire CL in the display device 20a includes a conductive wire CLa, a conductive wire CLb, a conductive wire CLc, and a conductive wire CLd. In the embodiment, the electrode Ea11, the electrode Ea21, the electrode Eb11, the electrode Eb21, the electrode Ec11, and the electrode Ec21 are P-type electrodes, and the electrode Ea12, the electrode Ea22, the electrode Eb12, the electrode Eb22, the electrode Ec12, and the electrode Ec22 are N-type electrodes.

The conductive wire CLa includes a conductive wire CLa1 electrically connected with the pad MPa12 and the redundant pad RPa12 and a conductive wire CLa2 electrically connected with the pad MPa11, the redundant pad RPa11, the pad MPa22, and the redundant pad RPa22.

The conductive wire CLb includes a conductive wire CLb1 electrically connected with the pad MPb12 and the redundant pad RPb12 and a conductive wire CLb2 electrically connected with the pad MPb11, the redundant pad RPb11, the pad MPb22, and the redundant pad RPb22.

The conductive wire CLc includes a conductive wire CLc1 electrically connected with the pad MPc12 and the redundant pad RPc12 and a conductive wire CLc2 electrically connected with the pad MPc11, the redundant pad RPc11, the pad MPc22, and the redundant pad RPc22.

The conductive wire CLd is electrically connected with the pad MPa21, the redundant pad RPa21, the pad MPb21, the redundant pad RPb21, the pad MPc21, and the redundant pad RPc21.

Through the configuration of the aforementioned conductive wire CLa, the conductive wire CLb, and the conductive wire CLc, the light-emitting unit Ea1 and the light-emitting unit Ea2 are in a series connection relationship with each other, the light-emitting unit Eb1 and the light-emitting unit Eb2 are in a series connection relationship with each other, and the light-emitting unit Ec1 and the light-emitting unit Ec2 are in a series connection relationship with each other.

Furthermore, through the electrical connection relationship between the aforementioned pads and redundant pads respectively with corresponding conductive wire CL, the embodiment may design the conductive wire CLd as a common anode line to reduce the layout area of the display device 20a. However, in other embodiments, the electrode Ea11, the electrode Ea21, the electrode Eb11, the electrode Eb21, the electrode Ec11, and the electrode Ec21 may be designed as N-type electrodes, and the electrode Ea12, the electrode Ea22, the electrode Eb12, the electrode Eb22, the electrode Ec12, and the electrode Ec22 may be designed as P-type electrodes so as to design the conductive wire CLd as a common cathode line, which may also reduce the layout area of the display device 20a.

Continuing to refer to FIG. 8, when detecting that the first group of light-emitting units Ea, the second group of light-emitting units Eb and/or the third group of light-emitting units Ec have a defect, a first group of light-emitting units Ea', a second group of light-emitting units Eb′, and a third group of light-emitting units Ec′ may be respectively bonded to the redundant pad RPa, the redundant pad RPb, and the redundant pad RPc. In detail, electrodes Ea11′, Ea12′ are respectively electrically connected with the redundant pads RPa11, RPa12, and electrodes Ea21′, Ea22′ are electrically connected with the redundant pads RPa21, RPa22. Electrodes Eb11′, Ea12′ are electrically connected with the redundant pads RPb11, RPb12, and electrodes Eb21′, Eb22′ are electrically connected with the redundant pads RPb21, RPb22. Electrodes Ec11′, Ec12′ are electrically connected with the redundant pads RPc11, RPc12, and electrodes Ec21′, Ec22′ are electrically connected with the redundant pads RPc21, RPc22.

Continuing to refer to FIG. 8, a laser cutting process may be used to cut off a portion of the conductive wire CLa electrically connected with the first group of light-emitting units Ea, a portion of the conductive wire CLb electrically connected with the second group of light-emitting units Eb, and a portion of the conductive wire CLc electrically connected with the third group of light-emitting units Ec, so as to reduce the influence generated by the first group of light-emitting units Ea′, the second group of light-emitting units Eb′, and/or the third group of light-emitting units Ec′.

Based on the above, when detecting that at least one of the first group of light-emitting units Ea, the second group of light-emitting units Eb, and the third group of light-emitting units Ec has a defect, the first group of light-emitting units Ea′, the second group of light-emitting units Eb′, and the third group of light-emitting units Ec′ are disposed by performing the repair method of the embodiment. Based on this, the pixel composed of the first group of light-emitting units Ea, the second group of light-emitting units Eb, and the third group of light-emitting units Ec has no offset in direction X and direction Y compared with the pixel composed of the first group of light-emitting units Ea′, the second group of light-emitting units Eb′, and the third group of light-emitting units Ec′. Through the design, the possibility of display quality degradation of the display device may be reduced.

Furthermore, since the light-emitting unit Ea1 and the light-emitting unit Ea2 (the light-emitting unit Eb1 and the light-emitting unit Eb2 as well as the light-emitting unit Ec1 and the light-emitting unit Ec2) are connected in series with each other, the light-emitting unit Ea1 and the light-emitting unit Ea2 (the light-emitting unit Eb1 and the light-emitting unit Eb2 as well as the light-emitting unit Ec1 and the light-emitting unit Ec2) may be detected together, and when a defect is detected, the first group of light-emitting units Ea′, the second group of light-emitting units Eb′, and/or the third group of light-emitting units Ec′ may be simultaneously transferred for repair, which may reduce detection time and/or repair time.

Additionally, taking the light-emitting unit Ea as an example, through the electrical connection relationship between the above-mentioned pads and redundant pads respectively with the corresponding conductive wire CL, when a defect is detected, multiple light-emitting units Ea′ may be simultaneously transferred to corresponding redundant pads by performing one transfer process, thereby reducing repair time and/or process cost. In some embodiments, the light-emitting unit Eb and the light-emitting unit Ec may be transferred together with the light-emitting unit Ea in one transfer process.

Furthermore, through the configuration of the above-mentioned conductive wire CLa, conductive wire CLb, conductive wire CLc, and conductive wire CLd in this embodiment, the light emitted by light-emitting unit Ea, light-emitting unit Eb, and light-emitting unit Ec in one pixel may have a more uniformly mixed color.

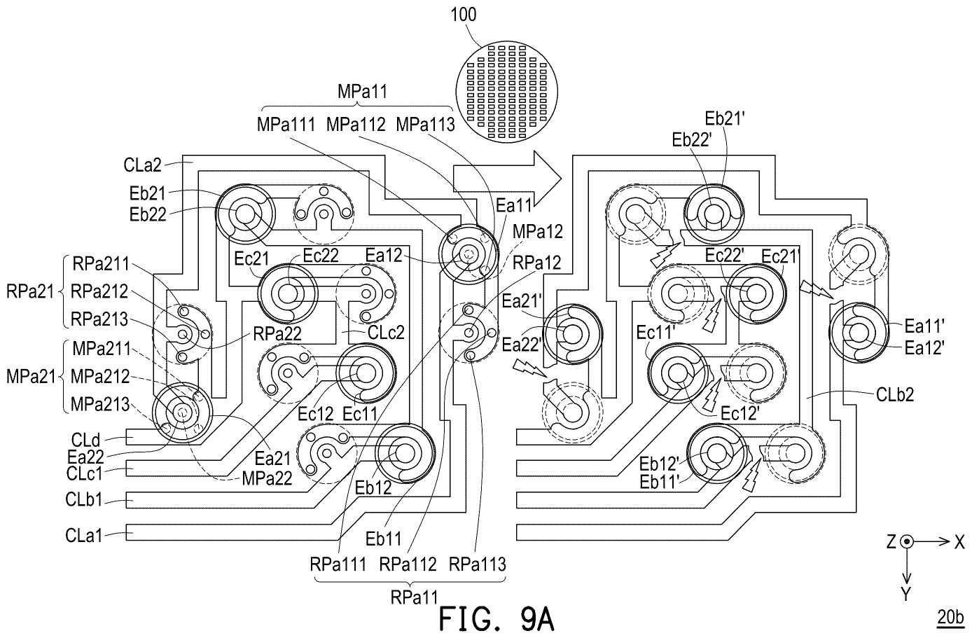

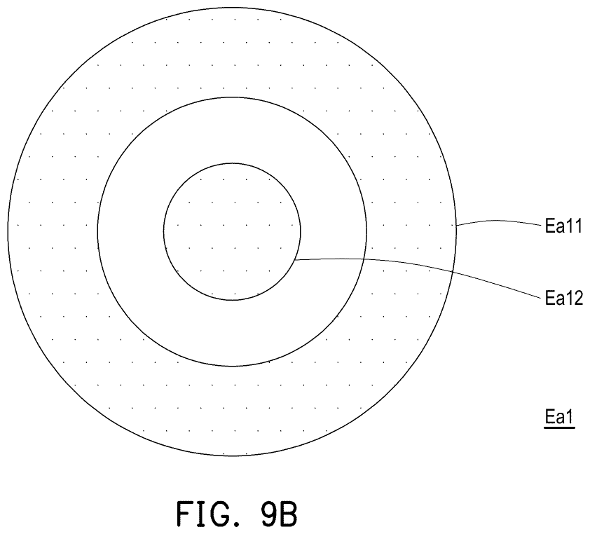

Referring to FIG. 9A and FIG. 9B, the following will state the main differences between the display device 20b and the display device 20a below.

In the embodiment, the light-emitting unit Ea, the light-emitting unit Eb, and the light-emitting unit Ec in the display device 20b have concentric circle shapes, where the outer ring portion and the inner circle portion respectively have different polarities. For example, the outer ring portions of light-emitting unit Ea, light-emitting unit Eb, and light-emitting unit Ec are N-type electrodes, and the inner circle portions of light-emitting unit Ea, light-emitting unit Eb, and light-emitting unit Ec are P-type electrodes.

In the embodiment, taking the first group of pads MPa as an example, the pad MPa1 and the pad MPa2 in the first group of pads MPa include pads MPa11, MPa12 (e.g., including three pads MPa121, MPa122, MPa123) and pads MPa21, MPa22 (e.g., including three pads MPa221, MPa222, MPa223) that are separated from each other.

In the embodiment, taking the first group of redundant pads RPa as an example, the redundant pad RPa1 and the redundant pad RPa2 in the first group of redundant pads RPa include redundant pads RPa11, RPa12 (e.g., including three redundant pads RPa121, RPa122, RPa123) and redundant pads RPa21, RPa22 (e.g., including three redundant pads RPa221, RPa222, RPa223) that are separated from each other.

In the embodiment, the electrode Ea11, the electrode Ea21, the electrode Eb11, the electrode Eb21, the electrode Ec11, and the electrode Ec21 are P-type electrodes, and the electrode Ea12, the electrode Ea22, the electrode Eb12, the electrode Eb22, the electrode Ec12, and the electrode Ec22 are N-type electrodes.

In the embodiment, taking the conductive wire CLa1 and conductive wire CLa2 as examples, the conductive wire CLa1 is electrically connected to the pad MPa11 and the redundant pad RPa11, and the conductive wire CLa2 is electrically connected to the pad MPa12, the redundant pad RPa12, the pad MPa21, and the redundant pad RPa21.

Furthermore, through the electrical connection relationship between the aforementioned pads and redundant pads respectively with corresponding conductive wire CL, the embodiment may design the conductive wire CLd as a common cathode line to reduce the layout area of the display device 20b. However, in other embodiments, the electrode Ea11, the electrode Ea21, the electrode Eb11, the electrode Eb21, the electrode Ec11, and the electrode Ec21 may be designed as P-type electrodes, and the electrode Ea12, the electrode Ea22, the electrode Eb12, the electrode Eb22, the electrode Ec12, and the electrode Ec22 may be designed as N-type electrodes so as to design the conductive wire CLd as a common anode line, which may also reduce the layout area of the display device 20b.

In summary, when detecting that at least one of the first light-emitting unit and the second light-emitting unit has a defect, the third light-emitting unit and the fourth light-emitting unit may be disposed on corresponding redundant pads by performing the repair method of the display device provided by some embodiments of the disclosure, where after transferring the third light-emitting unit and the fourth light-emitting unit, the pixel composed of the third light-emitting unit and the fourth light-emitting unit has no offset in at least one direction compared to the pixel composed of the first light-emitting unit and the second light-emitting unit. Through the design, the possibility of display quality degradation of the display device may be reduced.

Furthermore, in some embodiments of the disclosure, the first light-emitting unit and the second light-emitting unit are in a series connection relationship, and therefore the first light-emitting unit and the second light-emitting unit may be detected together, and when detecting that at least one of them has a defect, the third light-emitting unit and the fourth light-emitting unit may be simultaneously transferred for repair, which may reduce the detection time and/or repair time of the display device of some embodiments of the disclosure.

What is claimed is:

1. A display device, comprising:
a first light-emitting unit;
a second light-emitting unit;
a first conductive wire, electrically connected to the first light-emitting unit and the second light-emitting unit;
a first redundant pad, electrically connected to the first conductive wire; and
a second redundant pad, electrically connected to the first conductive wire,
wherein the first light-emitting unit has a first electrode and a second electrode, the second light-emitting unit has a third electrode and a fourth electrode, the first conductive wire is electrically connected to the second electrode and the third electrode, and the second electrode and the third electrode have different polarities.

2. The display device according to claim 1, further comprising:
a second conductive wire, electrically connected to the first electrode of the first light-emitting unit;
a third conductive wire, electrically connected to the fourth electrode of the second light-emitting unit;
a third redundant pad, electrically connected to the second conductive wire; and
a fourth redundant pad, electrically connected to the third conductive wire.

3. The display device according to claim 2, wherein the first redundant pad and the third redundant pad form a first group of redundant pads, and the second redundant pad and the fourth redundant pad form a second group of redundant pads,
wherein the first light-emitting unit and the second light-emitting unit have a first pitch, the first group of redundant pads and the second group of redundant pads have a second pitch, and the first pitch and the second pitch conform to a relationship below:
$$p 1 * 0.9 ≦ p 2 ≦ p 1 * 1.1 ,$$
where p1 is the first pitch, and p2 is the second pitch.

4. The display device according to claim 3, wherein the first light-emitting unit and the second light-emitting unit have a first center position, the first group of redundant pads and the second group of redundant pads have a second center position, and a distance between the first center position and the second center position in a first direction is less than or equal to a farthest distance between the first light-emitting unit and the second light-emitting unit in the first direction.

5. The display device according to claim 4, wherein a distance between the first center position and the second center position in a second direction is less than or equal to a farthest distance between the first light-emitting unit and the second light-emitting unit in the second direction, and the second direction is perpendicular to the first direction.

6. The display device according to claim 1, wherein the first electrode and the second electrode have a first arrangement direction, the third electrode and the fourth electrode have a second arrangement direction, and the first arrangement direction and the second arrangement direction are the same.

7. The display device according to claim 1, wherein the first electrode and the second electrode have a first arrangement direction, the third electrode and the fourth electrode have a second arrangement direction, and the first arrangement direction and the second arrangement direction are different.

8. The display device according to claim 1, wherein the first light-emitting unit and the second light-emitting unit are configured to provide light of a same color.

9. The display device according to claim 1, further comprising:
a first group of pads, wherein the first light-emitting unit is bonded to the first group of pads; and
a second group of pads, wherein the second light-emitting unit is bonded to the second group of pads.

10. The display device according to claim 9, wherein the first redundant pad and the second redundant pad are disposed between the first group of pads and the second group of pads.

11. The display device according to claim 1, further comprising:
a second conductive wire, electrically connected to the first light-emitting unit and the second light-emitting unit, wherein the second conductive wire is a common anode line.

12. The display device according to claim 1, further comprising:
a second conductive wire, electrically connected to the first light-emitting unit and the second light-emitting unit, wherein the second conductive wire is a common cathode line.

13. A repair method of a display device, wherein the display device comprises a first light-emitting unit, a second light-emitting unit, a first group of redundant pads, and a second group of redundant pads, the first group of redundant pads is electrically connected to the first light-emitting unit, the second group of redundant pads is electrically connected to the second light-emitting unit, and the repair method of the display device comprises:
providing a substrate, wherein the substrate comprises a third light-emitting unit and a fourth light-emitting unit;
bonding the third light-emitting unit to the first group of redundant pads; and
bonding the fourth light-emitting unit to the second group of redundant pads,
wherein the first group of redundant pads and the second group of redundant pads are connected in series with each other after the third light-emitting unit and the fourth light-emitting unit are joined.

14. The repair method of the display device according to claim 13, wherein after bonding the third light-emitting unit to the first group of redundant pads and bonding the fourth light-emitting unit to the second group of redundant pads, a laser cutting process is used to cut off a portion of a first conductive wire.

15. The repair method of the display device according to claim 13, wherein the display device further comprises:
a first group of pads, wherein the first light-emitting unit is bonded to the first group of pads; and
a second group of pads, wherein the second light-emitting unit is bonded to the second group of pads.

16. The repair method of the display device according to claim 13, wherein in the step of bonding the third light-emitting unit to the first group of redundant pads and bonding the fourth light-emitting unit to the second group of redundant pads, the third light-emitting unit and the fourth light-emitting unit are transferred in one transfer process.

17. The repair method of the display device according to claim 13, wherein the first light-emitting unit and the second light-emitting unit have a first pitch, the first group of redundant pads and the second group of redundant pads have a second pitch, and the first pitch and the second pitch conform to a relationship below:
$$p 1 * 0.9 ≦ p 2 ≦ p 1 * 1.1 ,$$
where p1 is the first pitch, and p2 is the second pitch.

18. The repair method of the display device according to claim 13, wherein before the step of bonding the third light-emitting unit to the first group of redundant pads and bonding the fourth light-emitting unit to the second group of redundant pads, detecting the first light-emitting unit and the second light-emitting unit to check whether the first light-emitting unit and/or the second light-emitting unit have a defect.

19. The repair method of the display device according to claim 18, wherein at least one of the first light-emitting unit and the second light-emitting unit has a defect.

20. The repair method of the display device according to claim 13, wherein the first light-emitting unit and the second light-emitting unit are configured to provide light of a same color.
